(19) United States
(12) Patent Application Publication
(10) Pub. No.: US 2026/0087204 A1
(43) Pub. Date: Mar. 26, 2026

(54) Dual Meshing Method and System for Transformer Winding

(71) Applicant: Guizhou Power Grid Co., Ltd., Guiyang (CN)

(72) Inventors: Song ZHANG, Guiyang (CN); Yongxiang CAI, Guiyang (CN); Xiaobin XIAO, Guiyang (CN); Yaping DU, Guiyang (CN); Yutao XU, Guiyang (CN); Yue LI, Guiyang (CN); Huaifei CHEN, Guiyang (CN); Ruihan QI, Guiyang (CN); Lei JIA, Guiyang (CN); Xiaomeng HE, Guiyang (CN); Ke FAN, Guiyang (CN); Mingjun HE, Guiyang (CN); Xu LI, Guiyang (CN); Shuqing HAO, Guiyang (CN); Hengrong ZHANG, Guiyang (CN); Youzhuo ZHENG, Guiyang (CN); Anjiang LIU, Guiyang (CN); Yang WANG, Guiyang (CN); Yu MIAO, Guiyang (CN); Kaiyan LI, Guiyang (CN); Huayang YE, Guiyang (CN); Xinhao LI, Guiyang (CN); Qianmin LI, Guiyang (CN); Xinyu YOU, Guiyang (CN)

(21) Appl. No.: 19/407,677

(22) Filed: Dec. 3, 2025

Related U.S. Application Data
(63) Continuation of application No. PCT/CN2024/141462, filed on Dec. 23, 2024.

(30) Foreign Application Priority Data
Sep. 26, 2024 (CN) 202411348317.4

(51) Int. Cl. G06F 30/23; H01F 27/28

(52) U.S. Cl. CPC G06F 30/23; H01F 27/28

(57) ABSTRACT

The present invention discloses a dual meshing method and system for a transformer winding, comprising acquiring the working frequency of a target transformer, and carrying out a first meshing operation on the winding of the target transformer according to the working frequency with the combination of a first meshing strategy; carrying out a second meshing operation on the target transformer winding after the first meshing operation with the combination of a second meshing strategy; and acquiring the mesh size of the target transformer winding after the second meshing operation, and completing meshing on the target transformer according to the mesh size. By reasonably allocating the mesh sizes, the distribution of electromagnetic fields in the transformer winding can be accurately simulated, the consumption of calculation resources can be reduced on the promise of ensuing the accuracy, the simulation efficiency and the accuracy of the simulation result can be improved.

### CROSS-REFERENCE TO RELATED APPLICATIONS

The present application is a continuation of International Application No. PCT/CN2024/141462, filed on Dec. 23, 2024, which claims priority to Chinese Patent Application No. 202411348317.4, filed on Sep. 26, 2024, the entire disclosure of which is incorporated herein by reference.

### TECHNICAL FIELD

The present invention relates to the technical field of transformer winding meshing, and in particular relates to a dual meshing method and system for a transformer winding.

### BACKGROUND

In simulation and analysis of transformer windings, a traditional meshing method often fails to balance the calculation accuracy and calculation efficiency. To enhance the accuracy of simulation results and reduce the consumption of calculation resources, a dual meshing method emerges. According to the method, finer mesh sizes are adopted in critical areas and coarser mesh sizes in non-critical areas, thereby enhancing the calculation efficiency while maintaining the accuracy.

However, a conventional dual meshing method still has problems in practical application. For example, how to accurately recognize critical areas, how to reasonably select mesh sizes and how to effectively carry out mesh transition, and the like, need further research and improvement.

### SUMMARY

The purpose of the section is to overview some aspects of embodiments of the present invention and to briefly introduce some of preferable embodiments. In the section as well as in the abstract and title of the present application, some simplifications or omissions may be made to avoid making the purpose of the section, the abstract and the title ambiguous, but such simplifications or omissions cannot be used to limit the scope of the present invention.

In view of the existing problems above, the present invention is disclosed.

Therefore, the present invention provides a dual meshing method and system for a transformer winding to solve the technical problems in the background art.

In order to solve the above technical problems, the present invention provides the following technical solutions:

On a first aspect, the present invention provides a dual meshing method for a transformer winding, including:
acquiring the working frequency of a target transformer, and carrying out a first meshing operation on the winding of the target transformer according to the working frequency with the combination of a first meshing strategy;
carrying out a second meshing operation on the target transformer winding after the first meshing operation with the combination of a second meshing strategy; and
acquiring the mesh size of the target transformer winding after the second meshing operation, and completing meshing on the target transformer according to the mesh size.

As a preferable solution of the dual meshing method for the transformer winding of the present invention, the first meshing strategy includes:
taking the target transformer as an entirety, and acquiring overall geometric parameters of the target transformer winding, wherein the overall geometric parameters at least comprise length, diameter and core size;
selecting a primary mesh size h₁ for length, h₁=1/10·λ, wherein λ refers to a wavelength, acquired through the working frequency of the target transformer; and
primarily simulating a target transformer winding model based on the primary mesh size h₁, and recognizing a first critical area of the target transformer winding according to the primary simulation result.

As a preferable solution of the dual meshing method for the transformer winding of the present invention, the first meshing strategy further includes:
meshing the first critical area into a plurality of subareas, wherein the mesh size of each subarea is h_{2,i}, h_{2,i}=kᵢ·λ, and kᵢ is a proportion coefficient for each area;
defining the mesh transition size between the critical area and a non-critical area as h₃; and
re-carrying out primary simulation according to h₁, h_{2,i}, and h₃ after meshing, and judging whether the primary simulation result meets the accuracy requirement or not.

As a preferable solution of the dual meshing method for the transformer winding of the present invention, the judging whether the primary simulation result meets the accuracy requirement or not includes: presetting a first meshing strategy target function and a first constraint condition, and judging whether the primary simulation result meets the accuracy requirement or not according to the value of the first meshing strategy target function under the first constraint condition.

As a preferable solution of the dual meshing method for the transformer winding of the present invention, the second meshing strategy includes:
acquiring the primary simulation result of the target transformer winding after the first meshing operation, and acquiring a second critical area;
selecting a mesh size h₄ for a cross section, h₄=h₁/n, wherein n refers to a refining factor; and
meshing the second critical area into a plurality of subareas, wherein the mesh size of each subarea is h_{5,j}, h_{5,j}=kⱼ·λ, and kⱼ is a proportion coefficient for each area.

As a preferable solution of the dual meshing method for the transformer winding of the present invention, the second meshing strategy further includes:
defining the mesh transition size between the critical area and a non-critical area as h₆; and
re-carrying out simulation according to h₁, h_{2,i}, h₃, h₄, h_{5,j} [symbol] h₆ and after meshing, and judging whether the simulation result meets the accuracy requirement or not.

As a preferable solution of the dual meshing method for the transformer winding of the present invention, the second meshing strategy further includes: presetting a second meshing strategy target function and a second constraint condition, and judging whether the simulation result meets the accuracy requirement or not according to the value of the second meshing strategy target function under the second constraint condition.

On a second aspect, the present invention provides a dual meshing system for a transformer winding, including:
a first meshing module, used for acquiring the working frequency of a target transformer, and carrying out a first meshing operation on the winding of the target transformer according to the working frequency with the combination of a first meshing strategy;
a second meshing module, used for carrying out a second meshing operation on the target transformer winding after the first meshing operation with the combination of a second meshing strategy; and
a third meshing module, used for acquiring the mesh size of the target transformer winding after the second meshing operation, and completing meshing on the target transformer according to the mesh size.

On a third aspect, the present invention provides a computer device, including: a memory and a processor, wherein the memory is used for storing computer programs; and the steps of the method are achieved when the computer programs are executed by the processor.

On a fourth aspect, the present invention provides a computer readable storage medium, with computer programs stored thereon; and the steps of the method are achieved when the computer programs are executed by the processor.

Compared with the prior art, the present invention has the beneficial effects that: the present invention discloses the dual meshing method and system for the transformer winding, including acquiring the working frequency of the target transformer, and carrying out the first meshing operation on the winding of the target transformer according to the working frequency with the combination of the first meshing strategy; carrying out the second meshing operation on the target transformer winding after the first meshing operation with the combination of the second meshing strategy; and acquiring the mesh size of the target transformer winding after the second meshing operation, and completing meshing on the target transformer according to the mesh size. By adopting the dual meshing strategies, the present invention is capable of effectively improving the accuracy of the transformer winding simulation model, and at the same time reducing the consumption of calculation recourses. Specifically, the first meshing strategy mainly focuses on the length direction of the winding, and recognizes the critical area through the primary simulation result to carry out refining processing. The second meshing strategy further refines the critical area, and particularly carries out refined meshing on the cross section direction of the winding, thereby ensuring the accuracy of the simulation result.

To sum up, the dual meshing method and system of the present invention have the following advantages:
1. The simulation accuracy is improved: by adopting the dual meshing strategies, the distribution of electromagnetic fields in the transformer winding can be accurately simulated, and thus the accuracy of the simulation result can be improved.
2. Calculation resources are optimized: by reasonably allocating the mesh sizes, the consumption of calculation resources can be reduced on the promise of ensuing the accuracy, and the simulation efficiency can be improved.
3. Automated processing is achieved: the dual meshing method is achieved through computer programs, then the whole process is automated, artificial operation errors can be reduced, and the working efficiency can be improved.
4. The design reliability is improved: by adopting the dual meshing method, accurate simulation data can be provided for the design of transformers, and thus the design reliability of transformers can be improved.

In conclusion, the dual meshing method and system for the transformer winding, disclosed by the present invention, not only improve the simulation accuracy and efficiency, but also optimizes the use of calculation resources, and have wide application prospects.

### BRIEF DESCRIPTION OF DRAWINGS

In order to describe the technical solutions in the examples of the present disclosure more clearly, a brief description of the accompanying drawings required for describing the examples will be provided below. Obviously, the accompanying drawings in the following description show merely some examples of the present disclosure. Those of ordinary skill in the art can also derive other accompanying drawings from these accompanying drawings without making creative efforts. In the figures:

FIG. 1 is a method flow chart of a dual meshing method and system for a transformer winding provided by one embodiment of the present invention;

FIG. 2 is a schematic diagram of length meshing in the prior art of a dual meshing method and system for a transformer winding provided by one embodiment of the present invention;

FIG. 3 is a schematic diagram of cross section meshing in the prior art of a dual meshing method and system for a transformer winding provided by one embodiment of the present invention;

FIG. 4 is a schematic diagram of meshes after meshing in the prior art of a dual meshing method and system for a transformer winding provided by one embodiment of the present invention; and

FIG. 5 is an internal structural diagram of a computer device of a dual meshing method and system for a transformer winding provided by one embodiment of the present invention.

### DETAILED DESCRIPTION OF THE EMBODIMENTS

In order to make the aforementioned purposes, features and advantages of the present invention more apparent and comprehensible, detailed descriptions of specific embodiments of the present invention are provided below in conjunction with the appended drawings.

Apparently, the described embodiments are only part of the embodiments of the present invention, not all of them. On the basis of the examples of the present invention, all other examples obtained by those of ordinary skill in the art without creative efforts shall fall within the protection scope of the present invention.

### Example 1

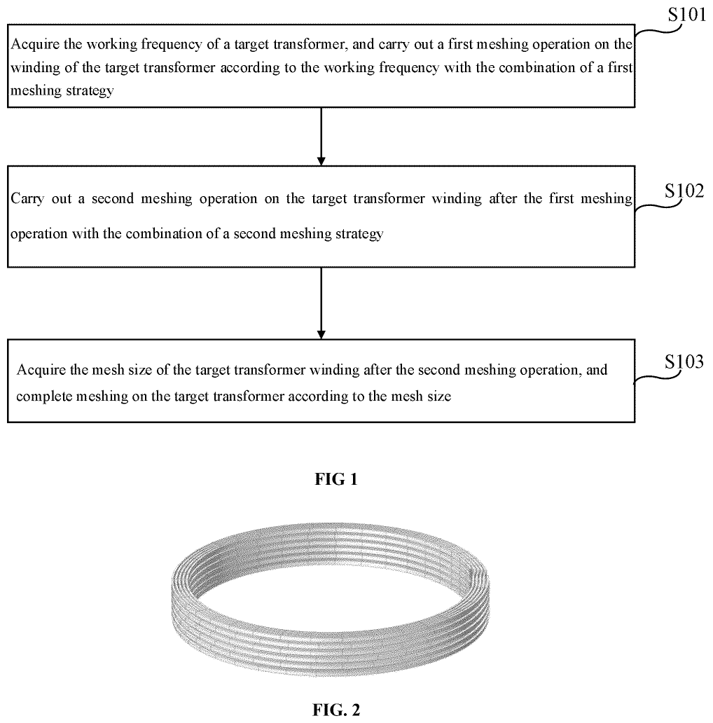

Referring to FIG. 1-FIG. 5, as a first embodiment of the present invention, the embodiment provides a dual meshing method and system for a transformer winding, including:

Before specifically explaining the embodiments of the present application, for the clarity, some related concepts are firstly explained.

Transformer winding: a transformer winding refers to a part responsible for transmitting electrical power inside a transformer, which is generally composed of multiple layers of insulating copper wires or aluminum wires wound together. A transformer winding can be a first winding (primary winding) and a second winding (secondary winding). The first winding receives the input voltage of a power supply, and the second winding outputs a transformed voltage. Design and manufacturing of windings directly affect the performance and efficiency of a transformer. In electric engineering, design of transformer windings relates to multiple aspects of material selection, insulating processing, heat dissipationn design, and the like.

Dual meshing: dual meshing is a method to improve electromagnetic simulation accuracy and efficiency, which is achieved by dividing meshes of transformer windings at two stages. According to the method, finer mesh sizes are adopted in critical areas and larger mesh sizes in non-critical areas, thereby reducing the demand on calculation resources while maintaining the accuracy. First meshing: mainly focuses on the length direction of a winding, and recognizes the critical area through the primary simulation result to carry out refining processing. Second meshing: further refines the critical area, and particularly carries out refined meshing on the cross section direction of a winding, thereby ensuring the accuracy of the simulation result. By adopting the dual meshing technology, the accuracy of a transformer winding simulation model can be effectively improved, and at the same time the consumption of calculation recourses can be reduced. By reasonably allocating the mesh sizes, not only is the simulation accuracy improved, but also the use of calculation resources is optimized. In addition, by adopting the method, accurate simulation data can be provided for the design of transformers, and thus the design reliability of transformers can be improved.

There are problems in related technologies, such as insufficient simulation accuracy, excessive consumption of calculation resources and tedious establishment of simulation models. These problems constrain design and optimization efficiency of transformers to a certain extent.

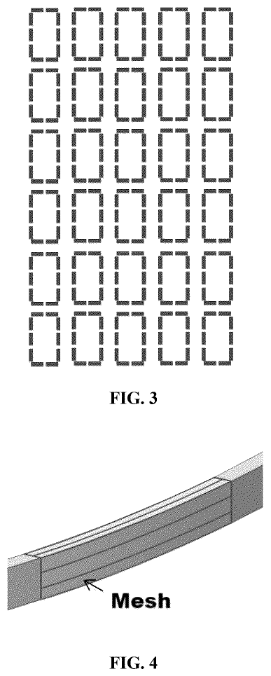

FIG. 2-4 show meshing modes of the prior art in the process of transformer winding simulation respectively. FIG. 2 is a schematic diagram of conventional length meshing, which illustrates that a winding is divided into multiple sections in a length direction. FIG. 3 is a schematic diagram of cross section meshing in the prior art, which illustrates that meshing is carried out on the cross section of windings of any section in FIG. 2 after meshing, and each cross section is divided into multiple units. FIG. 4 is a schematic diagram of final meshes divided by using the prior art shown in FIG. 2 and FIG. 3. In the prior art, coils of a transformer winding are simply divided vertically and transversely, but whether some areas are critical, or are parts requiring specific accurate simulation, is not specifically distinguished.

The present application provides the method and system to effectively solve the problems mentioned above, and how to achieve the dual meshing method for the transformer winding is specifically explained with the combination of multiple embodiments in the following.

FIG. 1 shows a method flow chart of a dual meshing method and system for a transformer winding, including:

S101, acquiring the working frequency of a target transformer, and carrying out a first meshing operation on the winding of the target transformer according to the working frequency with the combination of a first meshing strategy.

In the embodiment of the present application, the first meshing strategy includes:
taking the target transformer as an entirety, and acquiring overall geometric parameters of the target transformer winding, wherein the overall geometric parameters at least comprise length, diameter and core size;
selecting a primary mesh size h₁ for length, h₁=1/10·λ, wherein λ refers to a wavelength, acquired through the working frequency of the target transformer; and
primarily simulating a target transformer winding model based on the primary mesh size h₁, and recognizing a first critical area of the target transformer winding according to the primary simulation result.

What should be explained is that, the first critical area at least includes a winding end area, a winding and core contact area and a winding coupling area. These areas play a critical role in distribution of electromagnetic fields, and thus require particular attention to ensure the accuracy of simulation results.

In the embodiment of the present application, the first meshing strategy further includes:
meshing the first critical area into a plurality of subareas, wherein the mesh size of each subarea is h_{2,i}, h_{2,i}=kᵢ·λ, and kᵢ is a proportion coefficient for each area;
defining the mesh transition size between the critical area and a non-critical area as h₃; and

In the embodiment of the present application, the mesh transition size between the critical area and the non-critical area can be expressed as:

$${h}_{3} ( x ) = {h}_{1} + ( {h}_{2 , i} - {h}_{1} ) \cdot W 1$$

In the formula, x is a location coordinate in a transition area for length, x₁ is a start position of the transition area for length, and W 1 is a width proportion of the transition area for length.
re-carrying out primary simulation according to h₁, h_{2,i} and h₃ after meshing, and judging whether the primary simulation result meets the accuracy requirement or not.

In the embodiment of the present application, the primarily judging whether the simulation result meets the accuracy requirement or not includes: presetting a first meshing strategy target function and a first constraint condition, and judging whether the primary simulation result meets the accuracy requirement or not according to the value of the first meshing strategy target function under the first constraint condition.

In an optional embodiment, assume that e1 refers to a calculation error of an electromagnetic field under a low frequency condition, the first meshing strategy target function can be defined as follows:

$${F}_{{1}_{min}} = e 1 + a 1 * mesh number + a 2 * stability index$$

In the formula, e1 is the calculation error of the electromagnetic field under the low frequency condition, used for evaluating whether meshing leads to unstable values. a1 and a2 are weight coefficients, used for balancing accuracy, efficiency and stability.

What should be explained is that, in the first meshing strategy target function, there is no coefficient before e1, since the proportion of e1 is most important, and there is no simulation error or the error is very small should be first guaranteed. The number and stability of meshes behind are not highly required. e1 can be determined according to simulation values and standard values between different nodes, and stability indexes can be determined according to the norm ratio of a simulation residual vector to an original comparative residual vector in different areas acquired through residual analysis.

In the embodiment of the present application, the first constraint condition includes:

Minimum mesh size: the mesh size should not be smaller than a certain minimum value, so as to avoid insufficient calculation resources caused by excessively fine meshes.

Maximum mesh size: the mesh size should not too large either, so as to ensure certain calculation accuracy.

Mesh unit number constraint: the number of mesh units should not exceed a certain upper limit, so as to ensure the feasibility of calculation.

Calculation accuracy constraint: to ensure that the calculation error does not exceed a certain threshold.

What should be explained is that, the step S101 has the advantages that a mesh size can be primarily determined according to the working frequency and geometric parameters of the transformer, thereby providing a reasonable start point for subsequent simulation. Through the primary simulation result, critical areas are recognized and subjected to refining processing, thus ensuring that a higher simulation accuracy can be achieved in the critical area, and larger mesh sizes are adopted in non-critical areas, thereby saving calculation resources. By adopting the method, not only is the simulation efficiency improved, but also accurate simulation data can be provided for the design of transformers, and thus the design reliability can be improved.

S102, carrying out a second meshing operation on the target transformer winding after the first meshing operation with the combination of a second meshing strategy.

In the embodiment of the present application, the second meshing strategy includes:
acquiring the primary simulation result of the target transformer winding after the first meshing operation, and acquiring a second critical area;

What should be explained is that, the second critical area at least includes a high field intensity area inside the winding, an air gap area between the winding and the core, and a heat dissipation channel area of the winding. These areas play a critical role in performance and stability of the transformer, therefore refined simulation analysis is required to ensure efficient operation and long-time reliability of the transformer.
selecting a mesh size h₄ for a cross section, h₄=h₁/n, wherein n refers to a refining factor; and
meshing the second critical area into a plurality of subareas, wherein the mesh size of each subarea is h_{5,j}, h_{5,j}=kⱼ·λ, and kⱼ is a proportion coefficient for each area.

In the embodiment of the present application, the second meshing strategy further includes:
defining the mesh transition size between the critical area and a non-critical area as h₆; and

In the embodiment of the present application, the mesh transition size between the critical area and the non-critical area can be expressed as:

$${h}_{6} ( x ) = {h}_{4} + ( {h}_{5 , j} - {h}_{4} ) \cdot W 2$$

In the formula, y is a location coordinate in a transition area for the cross section, y₁ is a start position of the transition area for the cross section, and W2 is a width proportion of the transition area for the cross section.
re-carrying out simulation according to h₁, h_{2,i} h₃, h₄, h_{5,j} and h₆ after meshing, and judging whether the simulation result meets the accuracy requirement or not.

In the embodiment of the present application, the second meshing strategy further includes: presetting a second meshing strategy target function and a second constraint condition, and judging whether the simulation result meets the accuracy requirement or not according to the value of the second meshing strategy target function under the second constraint condition.

In an optional embodiment, assume that e2 refers to a calculation error of an electromagnetic field under a high frequency condition, the second meshing strategy target function can be defined as follows:

F₂_{ₘᵢₙ}=e2+a3* The number of meshes in critical areas+a4* stability index in critical area

In the formula, e2 is an electromagnetic field calculation error under a high frequency condition, and a3 and a4 are weight coefficients, used for balancing accuracy, efficiency and stability.

What should be explained is that, in the second meshing strategy target function, there is no coefficient before e2, since the proportion of e2 is most important, and there is no simulation error or the error is very small should be first guaranteed. The number and stability of meshes behind are not highly required. e2 can be determined according to simulation values and standard values between different nodes, and stability indexes can be determined according to the norm ratio of a simulation residual vector to an original comparative residual vector in critical areas acquired through residual analysis.

Exemplarily, for the first meshing strategy, a1=0.01,a2=0.001 can be selected, so as to ensure that on the promise of accuracy, the number of mesh units can be reduced as much as possible, and the stability is maintained. For the second meshing strategy, a3=0.1,a4=0.01 can be selected, so as to ensure that the critical area has sufficient accuracy, meanwhile the number of mesh unit is controlled, and the stability is maintained.

In the embodiment of the present application, the second constraint condition includes:

Mesh size constraint: to ensure that the mesh size of the critical area is not smaller than a certain minimum value.

Maximum mesh size in critical area: to ensure that the mesh size of the critical area is not greater than a certain maximum value.

Mesh unit number constraint: to ensure that the number of mesh units in the critical area does not exceed a certain upper limit.

Calculation accuracy constraint: to ensure that the calculation error in the critical area does not exceed a certain threshold.

What should be explained is that, the step S102 has the advantages that meshing in the critical area can be further refined, thereby ensuring accurate analysis on partial areas while ensuring the overall simulation accuracy. By adopting the dual meshing strategies, a higher simulation accuracy can be achieved in the critical area, and larger mesh sizes are adopted in non-critical areas, thereby saving calculation resources. By adopting the method, not only is the simulation efficiency improved, but also accurate simulation data can be provided for the design of transformers, and thus the design reliability can be improved.

S103, acquiring the mesh size of the target transformer winding after the second meshing operation, and completing meshing on the target transformer according to the mesh size.

In one optional embodiment, electromagnetic field simulation calculation can be carried out according to the target transformer winding model after meshing. In the simulation process, an advanced numerical calculation method is adopted, such as a finite element method (FEM) or a finite difference method (FDM), so as to ensure the accuracy and reliability of calculation results. In simulation calculation, factors such as material properties, geometric structures and boundary conditions of the transformer winding are considered, so as to simulate distribution of electromagnetic fields at an actual working state.

In one optional embodiment, the simulation result can also be analyzed, and key parameters are extracted, such as magnetic flux density, current density and consumption distribution. By comparing the simulation result with design requirements, whether the performance of the target transformer winding meets expected targets or not is evaluated. If the simulation result does not meet the design requirements, return to step S102, the meshing strategy is adjusted, and meshing in the critical area is optimized, so as to improve the simulation accuracy.

In one optional embodiment, the target transformer winding can be optimized according to the simulation result. In the optimization process, parameters such as the number of turns, wire routes and layout of the winding can be adjusted, so as to achieve the optimal performance. In optimization design, factors such as the electromagnetic performance, thermal performance and mechanical strength shall be comprehensively considered, so as to ensure the reliability and long-time stable operation of the transformer.

In one optional embodiment, manufacturing and test on an actual prototype can be carried out after the optimization design. The accuracy of the simulation result is verified through test, and performances, including key indexes such as load capability, efficiency and temperature rise, of the prototype, can be tested. If the test result meets the design requirement, volume production can be carried out. If the test result fails to meet the expected target, return to step S102 to carry out simulation analysis and optimization design.

In conclusion, the present invention discloses the dual meshing method for the transformer winding, including acquiring the working frequency of the target transformer, and carrying out the first meshing operation on the winding of the target transformer according to the working frequency with the combination of the first meshing strategy; carrying out the second meshing operation on the target transformer winding after the first meshing operation with the combination of the second meshing strategy; and acquiring the mesh size of the target transformer winding after the second meshing operation, and completing meshing on the target transformer according to the mesh size. By adopting the dual meshing strategies, the present invention is capable of effectively improving the accuracy of the transformer winding simulation model, and at the same time reducing the consumption of calculation recourses. Specifically, the first meshing strategy mainly focuses on the length direction of the winding, and recognizes the critical area through the primary simulation result to carry out refining processing. The second meshing strategy further refines the critical area, and particularly carries out refined meshing on the cross section direction of the winding, thereby ensuring the accuracy of the simulation result.

To sum up, the dual meshing method and system of the present invention have the following advantages:
1. The simulation accuracy is improved: by adopting the dual meshing strategies, the distribution of electromagnetic fields in the transformer winding can be accurately simulated, and thus the accuracy of the simulation result can be improved.
2. Calculation resources are optimized: by reasonably allocating the mesh sizes, the consumption of calculation resources can be reduced on the promise of ensuing the accuracy, and the simulation efficiency can be improved.
3. Automated processing is achieved: the dual meshing method is achieved through computer programs, then the whole process is automated, artificial operation errors can be reduced, and the working efficiency can be improved.
4. The design reliability is improved: by adopting the dual meshing method, accurate simulation data can be provided for the design of transformers, and thus the design reliability of transformers can be improved.

In conclusion, the dual meshing method and system for the transformer winding, disclosed by the present invention, not only improve the simulation accuracy and efficiency, but also optimizes the use of calculation resources, and have wide application prospects.

The present embodiment also provides a dual meshing system for a transformer winding, including:
a first meshing module, used for acquiring the working frequency of a target transformer, and carrying out a first meshing operation on the winding of the target transformer according to the working frequency with the combination of a first meshing strategy;
a second meshing module, used for carrying out a second meshing operation on the target transformer winding after the first meshing operation with the combination of a second meshing strategy; and
a third meshing module, used for acquiring the mesh size of the target transformer winding after the second meshing operation, and completing meshing on the target transformer according to the mesh size.

The unit modules can be embedded into or independent from a processor of a computer device in the mode of hardware, and can also be stored in a memory of the computer device in the mode of software, being beneficial for the processor to call and execute corresponding operations of the modules.

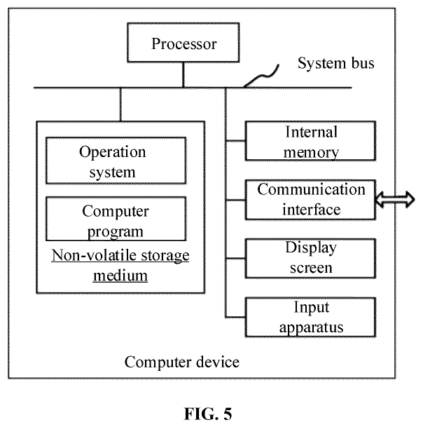

The present embodiment also provides a computer device, the computer device can be a terminal, and the internal structure thereof is as shown in FIG. 5. The computer device includes a processor, a memory, a communication interface, a display screen and an input device connected through system buses. The processor of the computer device is used for providing calculation and control capabilities. The memory of the computer device includes a non-volatile storage medium and an internal memory. The non-volatile storage medium stores an operating system and a computer program. The internal memory provides an environment for running of the operating system and the computer program in the non-volatile storage medium. The communication interface of the computer device is used for wired or wireless communication with external terminals, and a wireless mode can be achieved through WIFI, operator networks, NFC (near field communication) or other technologies. The dual meshing method for the transformer winding is achieved when the computer programs are executed by the processor. The display screen of the computer device may be a liquid crystal display screen or an electronic ink display screen, and the input apparatus of the computer device may be a touch layer covered on the display screen, or may be a button, a trackball, or a touchpad arranged on a shell of the computer device, or may be an external keyboard, touchpad or mouse.

The present embodiment also provides a computer readable storage medium, with computer programs stored thereon; and the steps of the method are achieved when the computer programs are executed by the processor:
acquiring the working frequency of a target transformer, and carrying out a first meshing operation on the winding of the target transformer according to the working frequency with the combination of a first meshing strategy;
carrying out a second meshing operation on the target transformer winding after the first meshing operation with the combination of a second meshing strategy; and
acquiring the mesh size of the target transformer winding after the second meshing operation, and completing meshing on the target transformer according to the mesh size.

It should be noted that the above examples are merely used to explain the technical solutions of the present disclosure and not intended to limit the present disclosure. Although the present disclosure is described in detail with reference to the preferred examples, those of ordinary skill in the art should understand that they can make modifications or equivalent substitutions to the technical solutions of the present disclosure without departing from the spirit and scope of the technical solutions of the present disclosure. These modifications or equivalent substitutions should fall within the scope of the claims of the present disclosure.

Those skilled in the art should understand that the embodiments of the present application can be provided as methods, systems, or computer program products. Therefore, the present application can take the form of embodiments of full hardwares, full softwares, or a combination of both softwares and hardwares. Moreover, the present application can be implemented in the form of a computer program product that is stored on one or more computer-readable storage media (including but not limited to disk storage, CD-ROM, optical storage, etc.) that contain computer-executable program codes. The solutions described in the embodiments of the present application can be implemented using various computer languages, such as object-oriented programming language Java and direct translation scripting language JavaScript.

The present application is described in reference to the flowcharts and/or block diagrams of the methods, devices (systems), and computer program products according to the embodiments of the present application. It should be understood that each process and/or box in the flowchart and/or block diagram, as well as the combination of processes and/or boxes in the flowchart and/or block diagram, can be implemented by computer program instructions. These computer program instructions can be provided to the processors of general-purpose computers, special-purpose computers, embedded processors or other programmable data processing devices to generate a machine, to enable the execution of the instructions by the processors of computers or other programmable data processing devices to produce a device that realizes the functions specified in a flowchart for one process or multiple processes, and/or in a block diagram for one block or multiple blocks.

These computer program instructions can also be stored in a computer-readable memory that can guide a computer or other programmable data processing device to work in a specific manner, so that the instructions stored in the computer-readable memory generate a product including an instruction device, where the instruction device implements functions specified in one or more processes in the flowcharts and/or one or more blocks in the block diagrams.

These computer program instructions can also be loaded onto computers or other programmable data processing devices, to enable a series of operation steps to be executed on the computer or other programmable device to generate the processing implemented by the computer, thereby the instructions executed on the computer or other programmable device provide steps for implementing the functions specified in a flowchart one process or multiple processes and/or in a block diagram one block or multiple blocks.

Although the preferred embodiments of the present application have been described, those skilled in the art can make additional changes and modifications to these embodiments once grasping the basic creative concept. Therefore, the appended claims are intended to cover all the preferred embodiments as well as all the variations and modifications falling within the scope of the present application.

Obviously, those skilled in the art can make various modifications and variations to the present application without departing from the spirit and scope of the present application. In this way, if these modifications and variations of the present application fall within the scope of the claims of the present application and its equivalents, the present application also intends to include these alterations and variations.

What is claimed is:

1. A dual meshing method for a transformer winding, comprising:
acquiring the working frequency of a target transformer, and carrying out a first meshing operation on the winding of the target transformer according to the working frequency with the combination of a first meshing strategy;
carrying out a second meshing operation on the target transformer winding after the first meshing operation with the combination of a second meshing strategy; and
acquiring the mesh size of the target transformer winding after the second meshing operation, and completing meshing on the target transformer according to the mesh size.

2. The dual meshing method for the transformer winding according to claim 1, wherein the first meshing strategy comprises:
taking the target transformer as an entirety, and acquiring overall geometric parameters of the target transformer winding, wherein the overall geometric parameters at least comprise length, diameter and core size;
selecting a primary mesh size h₁ for length, h₁=1/10·λ, wherein λ refers to a wavelength, acquired through the working frequency of the target transformer; and
primarily simulating a target transformer winding model based on the primary mesh size h₁, and recognizing a first critical area of the target transformer winding according to the primary simulation result.

3. The dual meshing method for the transformer winding according to claim 2, wherein the first meshing strategy further comprises:
meshing the first critical area into a plurality of subareas, wherein the mesh size of each subarea is h_{2,i}, h_{2,i}=kᵢ·λ, and kᵢ is a proportion coefficient for each area;
defining the mesh transition size between the critical area and a non-critical area as h₃; and
re-carrying out primary simulation according to h₁, h_{2,i} and h₃ after meshing, and judging whether the primary simulation result meets the accuracy requirement or not.

4. The dual meshing method for the transformer winding according to claim 3, wherein the judging whether the primary simulation result meets the accuracy requirement or not comprises: presetting a first meshing strategy target function and a first constraint condition, and judging whether the primary simulation result meets the accuracy requirement or not according to the value of the first meshing strategy target function under the first constraint condition.

5. The dual meshing method for the transformer winding according to claim 4, wherein the second meshing strategy comprises:
acquiring the primary simulation result of the target transformer winding after the first meshing operation, and acquiring a second critical area;
selecting a mesh size h₄ for a cross section, h₄=h₁/n, wherein n refers to a refining factor; and
meshing the second critical area into a plurality of subareas, wherein the mesh size of each subarea is h₅, h_{5,j}=kⱼ·λ, and kⱼ is a proportion coefficient for each area.

6. The dual meshing method for the transformer winding according to claim 5, wherein the second meshing strategy further comprises:
defining the mesh transition size between the critical area and a non-critical area as h₆; and
re-carrying out simulation according to h₁, h_{2,i} h₃, h₄, h_{5,j} and h₆ after meshing, and judging whether the simulation result meets the accuracy requirement or not.

7. The dual meshing method for the transformer winding according to claim 6, wherein the second meshing strategy further comprises: presetting a second meshing strategy target function and a second constraint condition, and judging whether the simulation result meets the accuracy requirement or not according to the value of the second meshing strategy target function under the second constraint condition.

8. A dual meshing system for a transformer winding, comprising:
a first meshing module, used for acquiring the working frequency of a target transformer, and carrying out a first meshing operation on the winding of the target transformer according to the working frequency with the combination of a first meshing strategy;
a second meshing module, used for carrying out a second meshing operation on the target transformer winding after the first meshing operation with the combination of a second meshing strategy; and
a third meshing module, used for acquiring the mesh size of the target transformer winding after the second meshing operation, and completing meshing on the target transformer according to the mesh size.

9. A computer device, including a memory and a processor, wherein the memory is used for storing computer programs; and the steps of the method according to claim 7 are achieved when the computer programs are executed by the processor.

10. A computer readable storage medium, with computer programs stored thereon, wherein the steps of the method according to claim 7 are achieved when the computer programs are executed by the processor.
